(19) United States
(12) Patent Application Publication
(10) Pub. No.: US 2008/0184557 A1
(43) Pub. Date: Aug. 7, 2008

(54) SURFACE MOUNTING DEVICE AND METHOD FOR FABRICATING A PRINTED CIRCUIT BOARD

(75) Inventor: Woo-Chul PARK, Gumi-si (KR)

Correspondence Address: Jefferson IP Law, LLP, 1730 M Street, NW, Suite 807, Washington, DC, 20036, US

(73) Assignee: SAMSUNG ELECTRONICS CO. LTD., Suwon-si (KR)

(21) Appl. No.: 11/841,563

(22) Filed: Aug. 20, 2007

(30) Foreign Application Priority Data
Feb. 1, 2007 (KR) 2007-10586

(51) Int. Cl. H05K 3/34; B23P 19/00

(52) U.S. Cl. 29/840; 29/742

(57) ABSTRACT

A surface mounting device and method for fabricating a printed circuit board (PCB) are provided. The device includes at least one pair of surface mounters, a feed conveyor for transporting a PCB to be fed to the surface mounters, a discharge conveyor for transporting a PCB to be discharged from the surface mounters and an elevator provided between the surface mounters, the elevator transporting a PCB discharged from one of the surface mounters to the discharge conveyor, and feeding a PCB transported by the feed conveyor to another one of the surface mounters. In a surface mounting device for a PCB configured as described above, each of the multiple surface mounters completes an assembly operation of integrated circuit chips on one PCB. Even when a failure or a malfunction occurs in one of the surface mounters, other surface mounters can normally continue an assembly operation because a feed and a discharge path of a PCB are set to bypass other surface mounters.

### PRIORITY

This application claims the benefit under 35 U.S.C. §119(a) of a Korean patent application filed on Feb. 1, 2007 in the Korean Intellectual Property Office and assigned Serial No. 2007-10586, the entire disclosure of which is hereby incorporated by reference.

### BACKGROUND OF THE INVENTION

1. Field of the Invention

The present invention relates to a device and method for manufacturing a printed circuit board (PCB). More particularly, the present invention relates to a surface mounting device and method for mounting chips and components on a PCB.

2. Description of the Related Art

Electrical and electronic devices have recently showed a tendency to become highly integrated and micro-sized. According to the tendency, there is no choice but to use a surface mounter, instead of a worker's manual labor, in assembling/manufacturing a PCB for electrical and electronic devices.

A surface mounter is a key unit for assembling micro-sized electrical/electronic components on a PCB, and transports feed components to mounting positions on a PCB and assembles them onto the PCB.

A surface mounter may be either a high-speed surface mounter or a universal surface mounter. A high speed surface mounter is suitable for mass production because it can mount a plurality of components in a short time, but it has low precision. A universal surface mounter is suitable for small quantity batch production because it can mount various components with relatively high precision but it has low speed.

In order to enable surface mounting with high precision and high speed and to overcome the above defects of both the high-speed and universal surface mounters, a method is used in which multiple universal surface mounters are operative to assemble and manufacture one kind of PCB.

FIG. 1 is a schematic diagram illustrating the structure of such a conventional surface mounting device 100 using multiple universal surface mounters. The conventional surface mounting device 100 includes a sequential arrangement of multiple surface mounters 101a, 101b and 101c, and is configured such that each of the surface mounters 101a, 101b and 101c mounts integrated circuit chips, etc. on a PCB sequentially passing therethrough.

Each of the surface mounters 101a, 101b and 101c mounts components on a PCB. Before a PCB is fed to the surface mounters 101a, 101b and 101c, solder lands are printed on the PCB by a solder printer 102, and it is determined whether or not the solder lands on the PCB are printed according to a given design. Therefore, between the solder printer 102 and the surface mounters 101a, 101b and 101c, a soldering pattern checker 129 is provided.

After passing through the soldering pattern checker 129, a PCB sequentially passes through the surface mounters 101a, 101b and 101c, and each of the surface mounters 101a, 101b and 101c mounts integrated circuit chips or components assigned thereto on the PCB.

The surface mounting device 100 includes a conveyor belt 104 extending through the surface mounters 101a, 101b and 101c from the solder printer 102, and thus a PCB discharged from the solder printer 102 sequentially passes through the surface mounters 101a, 101b and 101c by means of the conveyor belt 104.

When all integrated circuit chips and components are mounted by the surface mounters 101a, 101b and 101c, a PCB is fed to a different-type component mounter 103. The different-type component mounter 103 mounts components other than standardized IC chips, such as a variety of connectors and chip scale packages, etc., which are different according to products, on a PCB.

Warning lights 111, 121 and 131 for malfunction indication may be provided in each of the surface mounters 101a, 101b and 101c, the solder printer 102, and the different-type component mounter 103. When a failure or a malfunction occurs in the process of mounting a variety of components on a PCB, the surface mounting device 100 stops an operation in progress, and by the warning lights 111, 121 and 131, informs that the failure or malfunction has occurred.

For such a conventional surface mounting device, an operation progresses while a PCB sequentially passes through the surface mounters, which causes a problem in that other surface mounters have to stop when a failure or a malfunction occurs in one of the surface mounters.

Also, when a discrepancy occurs between operation processing times of the surface mounters, there is a problem in that an assembly operation of a PCB is delayed because chips are assembled according to the operation time of the surface mounter having the lowest speed.

In addition, when maintenance is required for one of the surface mounters, other mounters cannot operate and thus there is a problem in that productivity is reduced.

### SUMMARY OF THE INVENTION

An aspect of the present invention is to address the above-mentioned problems and/or disadvantages occurring in the prior art and to provide the advantages described below. Accordingly, as aspect of the present invention is to provide a surface mounting device and method for mounting components on a printed circuit board (PCB), which improves productivity by independently operating each of multiple surface mounters.

Another aspect of the present invention is to provide a surface mounting device and method for mounting components on a PCB, which can prevent a delay of an assembly operation by independently operating each of surface mounters even when there is a discrepancy between operation processing times of surface mounters.

Another aspect of the present invention is to provide a surface mounting device and method for mounting components on a PCB, which can continue an assembly operation of a PCB at other surface mounters even during maintenance on one of the surface mounters, thus improving productivity by independently operating each of surface mounters.

In accordance with an aspect of the present invention, a surface mounting device for a printed circuit board (PCB) is provided. The surface mounting device includes at least one pair of surface mounters, a feed conveyor for transporting a PCB to be fed to the surface mounters, a discharge conveyor for transporting a PCB to be discharged from the surface mounters and an elevator provided between the surface mounters, the elevator transporting a PCB discharged from one of the surface mounters to the discharge conveyor, and feeding a PCB transported by the feed conveyor to another one of the surface mounters.

In accordance with another aspect of the present invention, a surface mounting device for a PCB is provided. The surface mounting device includes a first, a second and a third surface mounter sequentially arranged, a feed elevator arranged in front of the first surface mounter, a first elevator arranged between the first and second surface mounters, a second elevator arranged between the second and third surface mounters, a discharge elevator arranged at the rear of the third surface mounter, a feed conveyor connected from the feed elevator to the second elevator via the first elevator and a discharge conveyor connected from the first elevator to the discharge elevator via the second elevator, wherein a PCB operated at the first surface mounter is fed via the feed elevator, and discharged by sequentially passing through the first elevator, the discharge conveyor and the discharge elevator, a PCB operated at the second surface mounter is fed by sequentially passing through the feed elevator, the feed conveyor, the first elevator, and discharged by sequentially passing through the second elevator, the discharge conveyor and the discharge elevator and a PCB operated at the third surface mounter is fed by sequentially passing through the feed elevator, the feed conveyor, the second elevator, and discharged via the discharge elevator.

In accordance with another aspect of the present invention, a method of assembling a PCB in a surface mounting device for a PCB is provided. The method includes searching for a surface mounter not performing an assembly operation of a PCB from at least two surface mounters when a PCB to be assembled is transported, feeding the transported PCB to the surface mounter not performing an assembly operation of a PCB and discharging the PCB when an assembly operation is completed.

In accordance with another aspect of the present invention, a method of assembling a PCB in a surface mounting device, wherein the device includes a sequential arrangement of a feed elevator, a first surface mounter, a first elevator, a second surface mounter, a second elevator, a third surface mounter and a discharge elevator, a feed conveyor connected from the feed elevator to the second elevator via the first elevator, and a discharge conveyor connected from the first elevator to the discharge elevator via the second elevator is provided. The method includes searching for a surface mounter not performing an assembly operation of a PCB from the first, second and third surface mounters when a PCB to be assembled is transported, feeding the transported PCB to the first surface mounter via the feed elevator when the first surface mounter of the first, second and third surface mounters does not perform an assembly operation of a PCB, performing an assembly operation, and discharging the operation-completed PCB by sequentially passing through the first elevator, the discharge conveyor, and the discharge elevator, feeding the transported PCB to the second surface mounter via the feed elevator, the feed conveyor, and the first elevator when the second surface mounter of the first, second and third surface mounters does not perform an assembly operation of a PCB, performing an assembly operation, and discharging the operation-completed PCB by sequentially passing through the second elevator, the discharge conveyor, and the discharge elevator and feeding the transported PCB to the third surface mounter via the feed elevator, the feed conveyor and the second elevator when the third surface mounter of the first, second and third surface mounters does not perform an assembly operation of a PCB, performing an assembly operation, and discharging the operation-completed PCB via the discharge elevator.

### BRIEF DESCRIPTION OF THE DRAWINGS

The above and other features, aspects, and advantages of certain exemplary embodiments of the present invention will be more apparent from the following detailed description taken in conjunction with the accompanying drawings, in which:

FIG. 1 is a schematic diagram illustrating the structure of a conventional surface mounting device for a printed circuit board (PCB);

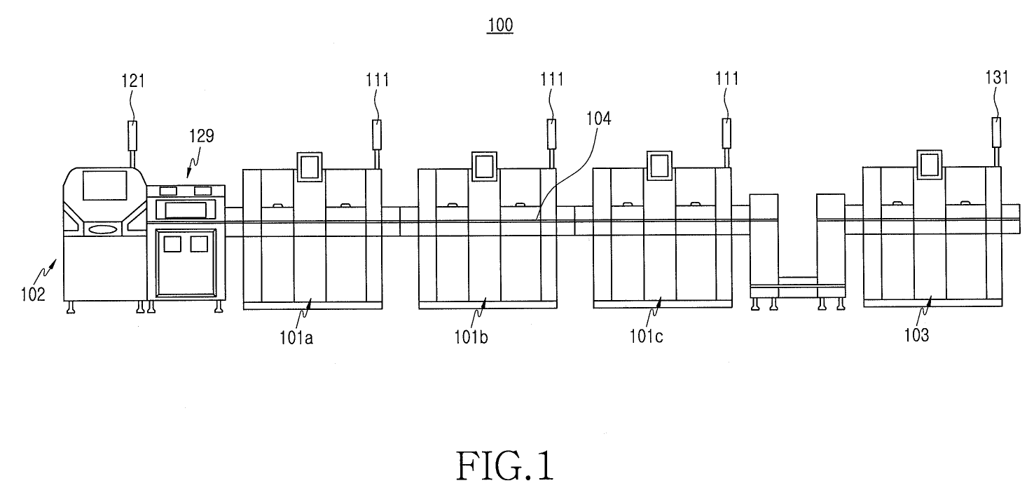

FIG. 2 is a schematic diagram illustrating the structure of a surface mounting device for a PCB according to an exemplary embodiment of the present invention;

FIG. 3 is a perspective view illustrating an exemplary structure of conveyors and elevators of a surface mounting device shown in FIG. 2; and

FIG. 4 is a flow diagram illustrating a process for an assembly operation of a surface mounting device for a PCB according to an exemplary embodiment of the present invention.

Throughout the drawings, it should be noted that like reference numbers are used to depict the same or similar elements, features and structures.

### DETAILED DESCRIPTION OF EXEMPLARY EMBODIMENTS

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. Also, descriptions of well-known functions and constructions are omitted for clarity and conciseness.

A surface mounting device for a printed circuit board (PCB) according to an exemplary embodiment of the present invention is configured to operate at least one or more pairs of surface mounters at once, to feed a PCB to a second surface mounter through a path bypassing a first surface mounter by using a feed conveyor and an elevator, and to transport a PCB discharged from the first surface mounter through a path bypassing the second surface mounter by using the elevator and a discharge conveyor. Also, each of the surface mounters is set to mount all required chips on one PCB, and thus each surface mounter discharges a PCB on which integrated circuit chips have been completely mounted. According to an environment of a workplace, three or more surface mounters may be provided. When the number of the surface mounters increases, an elevator is additionally provided between the surface mounters.

As described above, a PCB is independently fed to each surface mounter, and thus, even when one of the surface mounters stops an assembly operation of a PCB, another surface mounter can continue an assembly operation of a PCB.

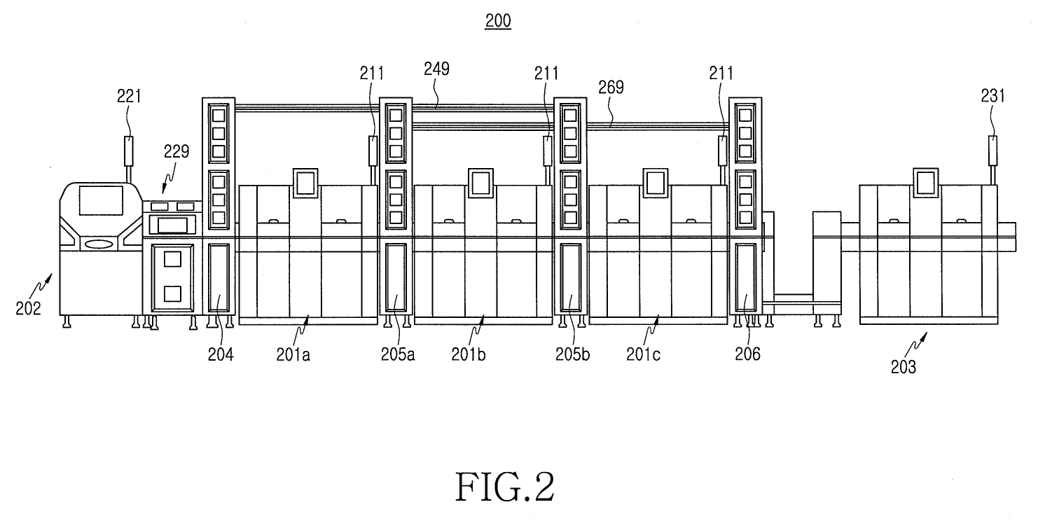

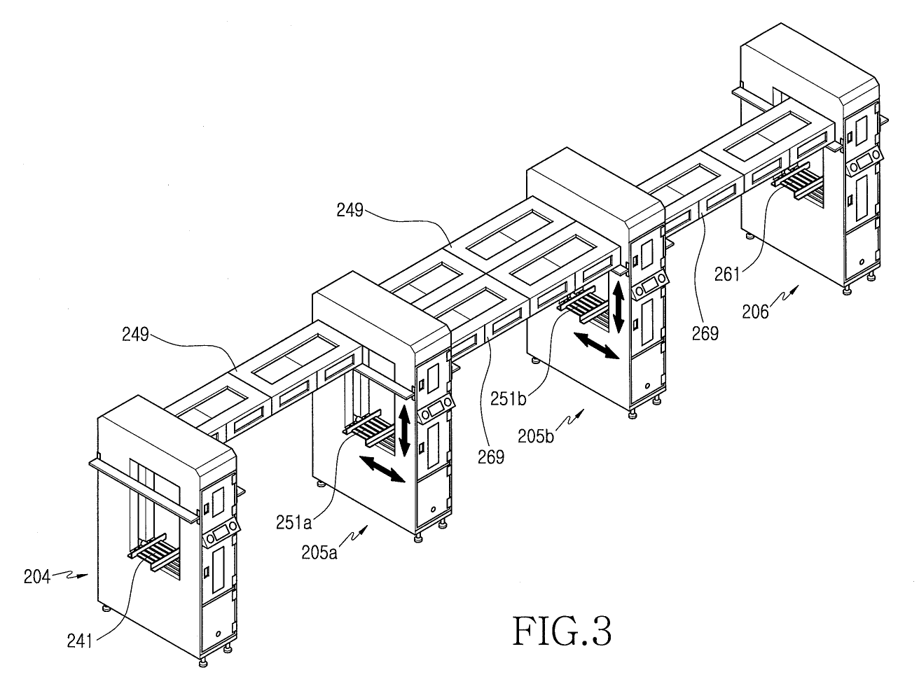

FIG. 2 is a schematic diagram illustrating the structure of a surface mounting device 200 according to an exemplary embodiment of the present invention. FIG. 3 is a perspective view illustrating an exemplary structure of conveyors 249 and 269, a feed elevator 204, a first and a second elevator 205a and 205b, and a discharge elevator 206 of a surface mounting device shown in FIG. 2. As shown in FIGS. 2 and 3, the surface mounting device 200 according to an exemplary embodiment of the present invention includes a first and a second elevator 205a and 205b provided between surface mounters. The first and second elevators 205a and 205b are connected with a feed conveyor 249 and a discharge conveyor 269 respectively, and thus a PCB to be fed to each surface mounter or to be discharged from each surface mounter can be transported through a path bypassing other surface mounters. Therefore, each of the surface mounters can independently operate for the assembly of a PCB.

The surface mounters have a sequential arrangement of a first, a second and a third surface mounter 201a, 201b and 201c. A solder printer 202 and a different-type component mounter 203 are arranged in front of the first surface mounter 201a, and at the rear of the third surface mounter 201c, respectively.

On each of the first, second and third surface mounters 201a, 201b and 201c, a tape reel (not shown) including an arrangement of chips to be mounted on one PCB is mounted, and thus each of the first, second and third surface mounters 201a, 201b and 201c may complete an assembly operation of one PCB. That is, all integrated circuit chips to be mounted on one PCB are assembled by one surface mounter.

The solder printer 202 is a unit for forming a soldering pattern on a PCB. By applying a solder on a PCB, for example a cream solder, the solder printer 202 forms solder lands at positions where a variety of integrated circuit chips will be assembled. After a PCB discharged from the solder printer 202 is fed to a soldering pattern checker 229, it is determined whether or not positions and sizes of solder lands are appropriate. Then the PCB is transported to each of the first, second and third surface mounters 201a, 201b and 201c.

After passing through the solder printer 202 and the soldering pattern checker 229, a PCB is transported via a feed elevator 204 provided in front of the first surface mounter 201a, the feed conveyor 249, and the first or the second elevator 205a or 205b. A PCB to be fed to the first surface mounter 201a is directly fed via the feed elevator 204.

A PCB discharged from each of the first, second and third surface mounters 201a, 201b and 201c is fed to the different-type component mounter 203. The different-type component mounter 203 mounts components other than standardized IC chips, such as a variety of connectors and chip scale packages, etc., which are different according to products, on a PCB.

A PCB discharged from each of the first and second surface mounters 201a and 201b is transported via the first or the second elevator 205a or 205b, the discharge conveyor 269, and a discharge elevator 206 provided at the rear of the third surface mounter 201c, and is fed to the different-type component mounter 203. Also, a PCB discharged from the third surface mounter 201c is fed to the different-type component mounter 203 via the discharge elevator 206.

Hereinafter, structures of the elevators 204, 205a, 205b and 206, and structures of the feed and the discharge conveyor 249 and 269 will be described in detail with reference to FIG. 3. Elevators are divided into a first and a second elevator 205a and 205b between the first, second and third surface mounters 201a, 201b and 201c, but each elevator has the same function despite the different position.

In addition, the feed conveyor 249 is extended from the feed elevator 204 to the second elevator 205b via the first elevator 205a, and transports a PCB to be fed to the second and third surface mounters 201b and 201c. Also, the discharge conveyor 269 is extended from the first elevator 205a to the discharge elevator 206 via the second elevator 205b, and transports a PCB discharged from each of the first and second surface mounters 201a and 201b. A PCB to be fed to the first surface mounter 201a is directly fed by the feed elevator 204, and a PCB discharged from the third surface mounter 201c is directly fed to the different-type component mounter 203 by the discharge elevator 206.

The feed elevator 204 is provided between the first surface mounter 201a and a soldering pattern checker 229, and transports a PCB discharged from the soldering pattern checker 229 to the first surface mounter 201a, or to the feed conveyor 249. A first moving table 241 is provided inside the feed elevator 204 so that the first moving table 241 can transport a PCB by moving up and down between an outlet of the soldering pattern checker 229 and the feed conveyor 249. In addition, the first moving table 241 provides a conveying path for a PCB to be fed to the first surface mounter 201a by connecting the outlet of the soldering pattern checker 229 with an inlet of the first surface mounter 201a.

The first elevator 205a provided between the first and second surface mounters 201a and 201b transports a PCB discharged from the first surface mounter 201a to the discharge conveyor 269, and feeds a PCB transported by the feed conveyor 249 to the second surface mounter 201b. Inside the first elevator 205a, a second moving table 251a is provided to be movable horizontally and up/down.

A PCB discharged from the first surface mounter 201a is transported to the discharge conveyor 269 by up and down movement of the second moving table 251a, and a PCB transported by the feed conveyor 249 is transported to the second surface mounter 201b.

The second elevator 205b provided between the second and third surface mounters 201b and 201c transports a PCB discharged from the second surface mounter 201b to the discharge conveyor 269, and feeds a PCB transported by the feed conveyor 249 to the third surface mounter 201c. Inside the second elevator 205b, a third moving table 251b is provided to be movable horizontally and up/down.

A PCB discharged from the second surface mounter 201b is transported to the discharge conveyor 269 by up and down movement of the third moving table 251b, and a PCB transported by the feed conveyor 249 is transported to the third surface mounter 201c.

The discharge elevator 206 provided between the third surface mounter 201c and the different-type component mounter 203 transports a PCB discharged from the third surface mounter 201c to the different-type component mounter 203, or transports a PCB transported by the discharge conveyor 269 to the different-type component mounter 203. Inside the discharge elevator 206, a fourth moving table 261 is provided so that the fourth moving table 261 can transport a PCB by moving up and down between an inlet of the different-type component mounter 203 and the discharge conveyor 269. In addition, the fourth moving table 261 provides conveying path for a PCB to be fed to the different-type component mounter 203 by connecting an outlet of the third surface mounter 201c with an inlet of the different-type component mounter 203.

As the feed conveyor 249 and the discharge conveyor 269 are arranged side by side, both the feed conveyor 249 and the discharge conveyor 269 cannot be arranged in the opposite direction of a conveying path for a PCB in the first, second and third surface mounters 201a, 201b and 201c. Therefore, the first, second, third and fourth moving tables 241, 251a, 251b and 261 are provided to be movable horizontally, as well as up and down.

That is, if the feed conveyor 249 is arranged in the opposite direction of a conveying path for a PCB in the first, second and third surface mounters 201a, 201b and 201c, the first moving table 241 of the feed elevator 204 can feed a PCB to the first surface mounter 201a or transport a PCB to the feed conveyor 249, just by moving up and down. However, a PCB transported by the discharge conveyor 269 is transported from a position where a PCB transported by the feed conveyor 249 is moved horizontally, and thus the second, third and fourth moving tables 251a, 251b and 261 is provided to be movable horizontally, as well as up and down.

In the same manner, if the discharge conveyor 269 is arranged in the opposite direction of a conveying path for a PCB in the first, second and third surface mounters 201a, 201b and 201c, the fourth moving table 261 of the discharge elevator 206 may be provided to be movable just up and down because a PCB transported by the feed conveyor 249 is transported from a position where a PCB transported by the discharge conveyor 269 is moved horizontally. However, the first, second and third moving tables 241, 251a and 251b are provided to be movable horizontally, as well as up and down.

In a surface mounting device 200 for a PCB according to an exemplary embodiment of the present invention, the feed conveyor 249 and the discharge conveyor 269 are arranged side by side above the first, second and third surface mounters 201a, 201b and 201c, but it is possible to arrange the feed conveyor 249 and the discharge conveyor 269 in a stack. When the feed conveyor 249 and the discharge conveyor 269 are arranged in a stack, the first to fourth moving tables 241, 251a, 251b and 261 can transport a PCB just by moving up and down.

Also, it is possible to arrange the feed conveyor 249 and the discharge conveyor 269 side by side at one side of the first, second and third surface mounters 201a, 201b and 201c, or to arrange separately at both sides of the first, second and third surface mounters 201a, 201b and 201c. When the feed conveyor 249 and the discharge conveyor 269 are arranged at one side or at both sides of the first, second and third surface mounters 201a, 201b and 201c, the first to fourth moving tables 241, 251a, 251b and 261 can transport a PCB just by moving horizontally.

The arrangement of a feed conveyor and a discharge conveyor may be properly set according to available space in a workplace.

In a surface mounting device 200 for a PCB configured as described above, according to an exemplary process for an assembly operation of each of the first, second and third surface mounters 201a, 201b and 201c, the solder printer 202 forms solder lands to a PCB on which integrated circuit chips will be assembled and feeds the PCB. A conveying path for a PCB to be fed to each surface mounter bypasses other surface mounters by a feed elevator 204, a feed conveyor 249, and a first and a second elevator 205a and 205b. Also, a conveying path for a PCB discharged from each surface mounter bypasses other surface mounters by a first and a second elevator 205a and 205b, a discharge conveyor 269, and a discharge elevator 206.

When a failure or a malfunction occurs in one of the first, second and third surface mounters 201a, 201b and 201c, a warning light 211 provided in the affected surface mounter operates. By the warning light, a worker can recognize a failure or a malfunction of a surface mounter, and perform maintenance with only the affected surface mounter stopped, while other surface mounters continue an assembly operation of integrated circuit chips, because a conveying path for a PCB fed to each surface mounter or discharged from each surface mounter is set to bypass other surface mounters. By additionally providing warning lights 221 and 231 on the solder printer 202 and the different-type component mounter 203 respectively, it is possible to inform a worker of a failure or a malfunction of each unit.

The surface mounting device 200 for a PCB illustrated in FIGS. 2 and 3 shows an example including three surface mounters. However, the number of the surface mounters may vary according to an operation processing speed of the solder printer 202, the soldering pattern checker 229, and the different-type component mounter 203.

That is, when an operation processing speed of the solder printer 202 and the soldering pattern checker 229 is low, a feed-starting time of a PCB is delayed, and thus, even when three surface mounters operate at once, an operation-starting time of each surface mounter may be delayed. Also, when an operation processing speed of the different-type component mounter 203 is low, an operation-ending time of a surface mounter may be delayed in order to discharge a PCB according to the operation processing speed of the different-type component mounter 203, even when the surface mounter completes the assembly of a PCB in advance. Therefore, when an operation processing speed of the solder printer 202, the soldering pattern checker 229, and the different-type component mounter 203 is low, during an operation from the solder printer 202 and the surface mounters to the different-type component mounter 203, smooth operation is possible by reducing the number of surface mounters.

On the other hand, when an operation processing speed of the solder printer 202, the soldering pattern checker 229 and the different-type component mounter 203 is fast, it is possible to add additional surface mounters. That is, when an operation processing speed of the solder printer 202, the soldering pattern checker 229 and the different-type component mounter 203 is fast, it is possible to add a number of surface mounters so as to increase the assembly speed of a PCB according to the operation processing speed.

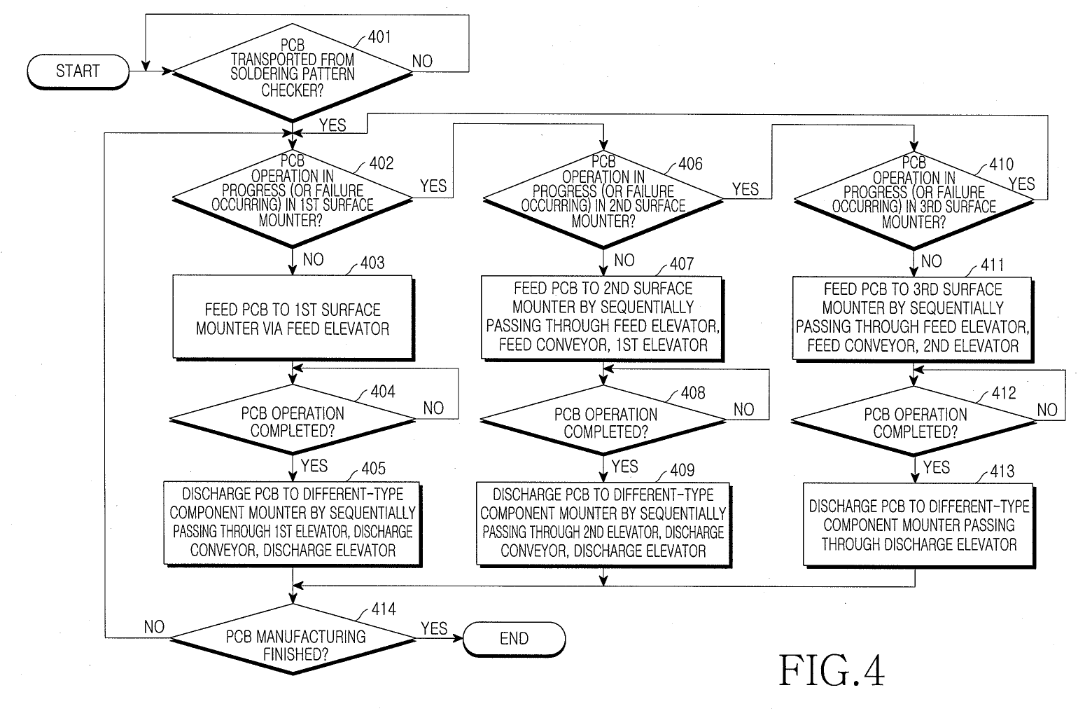

In the surface mounting device for a PCB configured as described above, an assembly operation of a PCB will be described in detail with reference to FIG. 4.

FIG. 4 is a flow diagram illustrating a process for an assembly operation of a surface mounting device for a PCB according to an exemplary embodiment of the present invention.

Hereinafter, an exemplary embodiment of the present invention will be described in detail with reference to FIGS. 2 and 3.

Referring to FIG. 4, a solder printer 202 applies a solder on a PCB, for example a cream solder, and forms solder lands at positions where a variety of integrated circuit chips will be assembled. After a PCB discharged from the solder printer 202 is fed to a soldering pattern checker 229, it is determined whether or not positions and sizes of solder lands are appropriate.

When a PCB is transported to a first to a third surface mounter 201a to 201c after passing through the solder printer 202 and the soldering pattern checker 229, a controller controlling the whole of a surface mounting device for a PCB senses it in step 401, and determines whether the first surface mounter 201a performs an assembly operation of a PCB instep 402.

When the first surface mounter 201a does not perform an assembly operation of a PCB, the controller senses it in step 402, and proceeds to step 403 in which the controller feeds the transported PCB to the first surface mounter 201a via a feed elevator 204.

However, in step 402, when a failure or a pause occurs in the first surface mounter 201a such that the first surface mounter 201a does not perform an assembly operation of a PCB, the controller senses it, and searches for another surface mounter which does not perform an assembly operation of a PCB, instead of feeding the PCB to the first surface mounter 201a.

When an assembly operation of the PCB fed to the first surface mounter 201a in step 403 is completed, the controller senses it in step 404, and proceeds to step 405 in which the controller discharges the operation-completed PCB to a different-type component mounter 203 by sequentially passing through a first elevator 205a, a discharge conveyor 269 and a discharge elevator 206.

Otherwise, when the first surface mounter 201a performs an assembly operation of a PCB, the controller senses it in step 402, and determines whether the second surface mounter 201b performs an assembly operation of a PCB in step 406.

When the second surface mounter 201b does not perform an assembly operation of a PCB, the controller senses it in step 406, and proceeds to step 407, in which the controller feeds the transported PCB to the second surface mounter 201b via a feed elevator 204, a feed conveyor 249 and a first elevator 205a.

However, when a failure or a pause occurs in the second surface mounter 201b while the second surface mounter 201b does not perform an assembly operation of a PCB, the controller senses it in step 406, and searches for another surface mounter which does not perform an assembly operation of a PCB, instead of feeding the PCB to the second surface mounter 201b.

When an assembly operation of the PCB fed to the second surface mounter 201b in step 407 is completed, the controller senses it in step 408, and proceeds to step 409, in which the controller discharges the operation-completed PCB to the different-type component mounter 203 by sequentially passing through a second elevator 205b, a discharge conveyor 269 and a discharge elevator 206.

Otherwise, when the second surface mounter 201b performs an assembly operation of a PCB, the controller senses it in step 406, and determines whether the third surface mounter 201c performs an assembly operation of a PCB in step 410.

When the third surface mounter 201c does not perform an assembly operation of a PCB, the controller senses it in step 410, and proceeds to step 411, in which the controller feeds the transported PCB to the third surface mounter 201c via a feed elevator 204, a feed conveyor 249 and a second elevator 205b.

However, when a failure or a pause occurs in the third surface mounter 201c while the third surface mounter 201c does not perform an assembly operation of a PCB, the controller senses it, and searches for another surface mounter which does not perform an assembly operation of a PCB, instead of feeding the PCB to the third surface mounter 201c.

When an assembly operation of the PCB fed to the third surface mounter 201c in step 411 is completed, the controller senses it in step 412, and proceeds to step 413, in which the controller discharges the operation-completed PCB to the different-type component mounter 203 via the discharge elevator 206.

Otherwise, when the third surface mounter 201c performs an assembly operation of a PCB, the controller senses it in step 410, and returns to step 402 where it is determined whether the first surface mounter 201a performs an assembly operation of a PCB.

The different-type component mounter 203 mounts components other than standardized IC chips, such as a variety of connectors and chip scale packages, etc., which are different according to products, on a PCB discharged from the step 405, 409, or 413.

While a manufacturing operation of a PCB in the surface mounting device for a PCB is not completed, the controller senses it in step 414, and performs an assembly operation of a PCB, by feeding a PCB transported from the soldering pattern checker 229 to one surface mounter not performing an assembly operation of a PCB from the first to third surface mounters 201a to 201c, in the process of repeatedly performing from step 402 to step 413.

As described above, a surface mounting device for a PCB according to an exemplary embodiment of the present invention completes an assembly operation of integrated circuit chips on one PCB at each of multiple surface mounters. Each surface mounter can independently perform an assembly operation because a feed and a discharge path of a PCB are set to bypass other surface mounters. Therefore, even when a failure or a malfunction occurs in one of the surface mounters, other surface mounters can normally continue an assembly operation, which can contribute to improving productivity. Also, because each surface mounter independently operates, even during regular maintenance on one of the surface mounters, other surface mounters can continue an assembly operation of a PCB, which can contribute to improving productivity.

In addition, even when there is a discrepancy between operation processing times of surface mounters, each surface mounter independently operates, and thus there is an advantage in that an assembly-operation delay by a surface mounter having a relatively low speed can be prevented.

While the invention has been shown and described with reference to certain exemplary embodiments thereof, it will be understood by those skilled in the art that various changes in form and details may be made therein without departing from the spirit and scope of the invention as defined by the appended claims and their equivalents.

What is claimed is:

1. A surface mounting device for a printed circuit board (PCB), the device comprising:
a plurality of surface mounters;
a feed conveyor for transporting a PCB to be fed to at least one of the plurality of surface mounters;
a discharge conveyor for transporting a PCB to be discharged from at least one of the plurality of surface mounters; and
an elevator, provided between at least two of the plurality of surface mounters, for transporting a PCB discharged from one of the plurality of surface mounters to the discharge conveyor and feeding a PCB transported by the feed conveyor to another one of the plurality of surface mounters.

2. The device as claimed in claim 1, further comprising a feed elevator arranged in front of a first surface mounter of the plurality of surface mounters.

3. The device as claimed in claim 2, wherein the feed elevator at least one of feeds a PCB to the first surface mounter and transports a PCB to the feed conveyor.

4. The device as claimed in claim 2, further comprising a solder printer arranged in front of the first surface mounter, wherein a PCB discharged from the solder printer is transported by the feed elevator to at least one of the first surface mounter and the feed conveyor.

5. The device as claimed in claim 1, further comprising a discharge elevator arranged at the rear of a second surface mounter of the plurality of surface mounters.

6. The device as claimed in claim 5, wherein the discharge elevator discharges at least one of a PCB discharged from the second surface mounter and a PCB transported by the discharge conveyor.

7. The device as claimed in claim 5, further comprising a component mounter arranged at the rear of the second surface mounter, wherein a PCB discharged from the discharge elevator is fed to the component mounter.

8. The device as claimed in claim 1, further comprising a plurality of elevators, wherein the plurality of surface mounters comprises three surface mounters sequentially arranged and each of the plurality of elevators is arranged between at least two of the surface mounters.

9. The device as claimed in claim 1, wherein the feed conveyor and the discharge conveyor are located above the plurality of surface mounters.

10. A surface mounting device for a PCB, the device comprising:
a first, a second and a third surface mounter sequentially arranged;
a feed elevator arranged in front of the first surface mounter;
a first elevator arranged between the first and second surface mounters;
a second elevator arranged between the second and third surface mounters;
a discharge elevator arranged at the rear of the third surface mounter;
a feed conveyor connected between the feed elevator and the second elevator via the first elevator; and
a discharge conveyor connected between the first elevator and the discharge elevator via the second elevator,
wherein a PCB operated on by the first surface mounter is fed to the first surface mounter via the feed elevator, and discharged by sequentially passing through the first elevator, the discharge conveyor and the discharge elevator;
a PCB operated on by the second surface mounter is fed to the second surface mounter by sequentially passing through the feed elevator, the feed conveyor and the first elevator, and discharged by sequentially passing through the second elevator, the discharge conveyor and the discharge elevator; and
a PCB operated on by the third surface mounter is fed to the third surface mounter by sequentially passing through the feed elevator, the feed conveyor and the second elevator, and discharged via the discharge elevator.

11. The device as claimed in claim 10, further comprising a solder printer arranged in front of the first surface mounter, wherein a PCB discharged from the solder printer is transported to at least one of the first surface mounter and the feed conveyor via the feed elevator.

12. The device as claimed in claim 10, further comprising a component mounter arranged at the rear of the third surface mounter, wherein at least one of a PCB discharged from the third surface mounter and a PCB transported by the discharge conveyor is fed to the component mounter by the discharge elevator.

13. A method of assembling a PCB in a surface mount device for a PCB, the method comprising:
searching for a surface mounter not performing an assembly operation of a PCB from a plurality of surface mounters when a PCB to be assembled is transported;
feeding the transported PCB to the surface mounter not performing an assembly operation of a PCB; and
discharging the PCB when an assembly operation is completed.

14. The method as claimed in claim 13, wherein the surface mount device for a PCB comprises first to third surface mounters sequentially arranged and wherein the searching for the surface mounter not performing an assembly operation comprises searching for a surface mounter from among the first, second and third surface mounters when the PCB is transported, the method further comprising:
sequentially feeding the transported PCB to the first, second and third surface mounters when all of the first, second and third surface mounters do not perform an assembly operation of a PCB, and discharging the PCB when an assembly operation is completed; and
feeding the transported PCB to the surface mounter not performing an assembly operation when one of the first, second and third surface mounters does not perform an assembly operation of a PCB, and discharging the PCB when an assembly operation is completed.

15. The method as claimed in claim 14, wherein the feeding of the transported PCB to the surface mounter comprises:
performing an assembly operation by feeding the transported PCB to the first surface mounter via a feed elevator arranged in front of the first surface mounter when the first surface mounter of the first, second and third surface mounters does not perform an assembly operation of a PCB; and
discharging the operation-completed PCB by sequentially passing through a first elevator arranged between the first and second surface mounters, a discharge conveyor for transporting a PCB to be discharged, and a discharge elevator arranged at the rear of the third surface mounter when an assembly operation of the PCB is completed.

16. The method as claimed in claim 14, wherein the feeding of the transported PCB to the surface mounter comprises:
feeding the transported PCB to the second surface mounter by sequentially passing through a feed elevator arranged in front of the first surface mounter, a feed conveyor for transporting a PCB to be fed, and a first elevator arranged between the first and second surface mounters when the second surface mounter of the first, second and third surface mounters does not perform an assembly operation of a PCB, and performing an assembly operation; and
discharging the operation-completed PCB by sequentially passing through a second elevator arranged between the second and third surface mounters, a discharge conveyor for transporting a PCB to be discharged, and a discharge elevator arranged at the rear of the third surface mounter when an assembly operation of the PCB is completed.

17. The method as claimed in claim 14, wherein the feeding of the transported PCB to the surface mounter comprises:
feeding the transported PCB to the third surface mounter by sequentially passing through a feed elevator arranged in front of the first surface mounter, a feed conveyor for transporting a PCB to be fed, and a second elevator arranged between the second and third surface mounters when the third surface mounter of the first, second and third surface mounters does not perform an assembly operation of a PCB, and performing an assembly operation; and
discharging the operation-completed PCB via a discharge elevator arranged at the rear of the third surface mounter when an assembly operation of the PCB is completed.

18. The method as claimed in claim 14, wherein the PCB is transported to one of the first, second and third surface mounters by passing through a solder printer and a soldering pattern checker which have been arranged in front of a feed elevator.

19. The method as claimed in claim 14, wherein, after an assembly operation of a PCB is completed at one of the first, second and third surface mounters, the PCB is discharged to a component mounter arranged at the rear of a discharge elevator.

20. A method of assembling a PCB in a surface mounting device for a PCB, wherein the mounting device comprises a sequential arrangement of a feed elevator, a first surface mounter, a first elevator, a second surface mounter, a second elevator, a third surface mounter and a discharge elevator, a feed conveyor connected from the feed elevator to the second elevator via the first elevator, and a discharge conveyor connected from the first elevator to the discharge elevator via the second elevator, the method comprising:
searching for a surface mounter not performing an assembly operation of a PCB from the first, second and third surface mounters when a PCB to be assembled is transported;
feeding the transported PCB to the first surface mounter via the feed elevator when the first surface mounter of the first, second and third surface mounters does not perform an assembly operation of a PCB, performing an assembly operation, and discharging the operation-completed PCB by sequentially passing through the first elevator, the discharge conveyor, and the discharge elevator;
feeding the transported PCB to the second surface mounter via the feed elevator, the feed conveyor, and the first elevator when the second surface mounter of the first, second and third surface mounters does not perform an assembly operation of a PCB, performing an assembly operation, and discharging the operation-completed PCB by sequentially passing through the second elevator, the discharge conveyor, and the discharge elevator; and
feeding the transported PCB to the third surface mounter via the feed elevator, the feed conveyor and the second elevator when the third surface mounter of the first, second and third surface mounters does not perform an assembly operation of a PCB, performing an assembly operation, and discharging the operation-completed PCB via the discharge elevator.

21. The method as claimed in claim 20, further comprising sequentially feeding the transported PCB to the first, second and third surface mounters when all of the first, second and third surface mounters do not perform an assembly operation of a PCB, and discharging the PCB when an assembly operation is completed.

22. The method as claimed in claim 20, wherein the PCB is transported to one of the first, second and third surface mounters by passing through a solder printer and a soldering pattern checker which have been arranged in front of the feed elevator.

23. The method as claimed in claim 20, wherein, after an assembly operation of a PCB is completed at one of the first, second and third surface mounters, the PCB is discharged to a different-type component mounter arranged at the rear of the discharge elevator.
